(19) United States
(12) Patent Application Publication
(10) Pub. No.: US 2006/0093076 A1
(43) Pub. Date: May 4, 2006

(54) Apparatus for estimating a frequency offset in a communication system and method thereof

(75) Inventors: Jae-Yong Lee, Seongnam-si (KR); Yun-Sang Park, Suwon-si (KR); Bong-Gee Song, Seongnam-si (KR)

Correspondence Address: DILWORTH & BARRESE, LLP, 333 EARLE OVINGTON BLVD., UNIONDALE, NY, 11553, US

(73) Assignee: SAMSUNG ELECTRONICS CO., LTD., Gyeonggi-do (KR)

(21) Appl. No.: 11/259,688

(22) Filed: Oct. 26, 2005

(30) Foreign Application Priority Data
Oct. 29, 2004 (KR) 87312/2004

(51) Int. Cl. H04L 27/06; H03D 1/04

(52) U.S. Cl. 375/343; 375/346

(57) ABSTRACT

An apparatus and method for estimating a frequency offset using a preamble signal having a periodically repeated structure. According to the apparatus and method, the sum of or the difference between an input signal and a delay signal is calculated without obtaining a simple correlation value between the input signal and the delay signal, and then a correlation value between a calculated signal and the delay signal is obtained. Accordingly, the implementation complexity of the circuit and the power consumption are reduced, and thus, the battery cycle of a terminal provided with the frequency offset estimating circuit can be increased.

### PRIORITY

This application claims priority to an application entitled “Apparatus for Estimating Frequency Offset in Communication System and Method Thereof” filed in the Korean Industrial Property Office on Oct. 29, 2004 and assigned Serial No. 2004-87312, the contents of which are hereby incorporated by reference.

### BACKGROUND OF THE INVENTION

1. Field of the Invention

The present invention relates generally to an apparatus for estimating a frequency offset in a receiver and a method thereof, which obtains synchronization using periodically repeated signal patterns.

2. Description of the Related Art

In a communication system, a transmitter transmits a sync signal to a receiver, and the receiver performs synchronization (or sync) using the sync signal. Recently, for a high-rate data transmission, a communication system using an OFDMA (Orthogonal Frequency Division Multiple Access) system has been proposed in the IEEE 802.16 committee. According to this IEEE 802.16 Standard, in the OFDMA type communication system, a transmitter transmits a preamble pattern to a receiver, and the receiver acquires the start of a frame, i.e., the frame sync, from the received preamble pattern.

FIG. 1 illustrates a preamble pattern used for an initial sync in a conventional communication system. Referring to FIG. 1, the preamble pattern 10 has repeated patterns 11, 12, and 13. In the two successive periods of such repeated patterns, for example, the receiver delays a signal of an ‘A’ period, correlates the delay signal of the ‘A’ period with a signal of a ‘B’ period, and sums the two signals. If the ‘A’ period signal and the ‘B’ period signal have the same pattern, their summed value maximizes. Because the repeated patterns 11, 12, and 13 have three periods, the correlation value between the repeated pattern 11 of the ‘A’ period and the repeated pattern 12 of the ‘B’ period and the correlation value between the repeated pattern 12 of the ‘B’ period and the repeated pattern 13 of the ‘C’ period should be accumulatively summed. Accordingly, if the respective signal period has m samples, 2m samples should be accumulatively summed. Further, if the same signals are repeated, a start point of a frame can be found by detecting the signal period in that the summed correlation value maximizes, and in the same manner, the frame sync can also be extracted.

A frequency offset occurs because of an oscillator error between the transmitter and the receiver. A conventional frequency offset estimating apparatus estimates the frequency offset by obtaining a phase difference between the presently received signal and the previously received delay signal, and provides the estimated frequency offset to the oscillator.

FIGS. 2A and 2B are views explaining a principle of obtaining the frequency offset. As illustrated in FIG. 2A, it is assumed that the presently received signal D of a specified section and the previously received delay signal E of a specified section exist. In this case, because the signal at the first point P1 in the section D is equal to the signal at the second point P2 in the section E, the frequency offset can be estimated by comparing the signal at the point P1 with the signal at the point P2 and obtaining the phase difference between them. This frequency offset is used to obtain the coincidence of the transmitted and received frequencies.

In summary, in order to estimate the phase difference of the same signal, the repeated patterns of the preamble pattern should be detected. Generally, a frequency offset estimating apparatus determines the point where the frequency offset will be obtained in the received signal according to the correlation values for obtaining the start position of the frame. That is, as illustrated in FIG. 2B, the point ñ in which the summed correlation value of the repeated patterns maximizes is detected. Thereafter, the frequency offset can be estimated from the accumulated correlation value for a period of 2m from the determined point.

As described above, according to the conventional frequency offset estimating apparatus, the repeated patterns 11, 12, and 13 have three signal periods, have three signal periods, and thus, if the respective signal period has m samples, 2m samples should accumulatively be summed. Consequently, this summing operation increases the circuit complexity and power consumption.

### SUMMARY OF THE INVENTION

Accordingly, the present invention has been designed to solve the above and other problems occurring in the prior art. An object of the present invention is to provide an apparatus and method for estimating a frequency offset that reduces the implementation complexity and power consumption in obtaining the frequency offset.

In order to accomplish the above and other objects, according to the apparatus and method for estimating a frequency offset, a frame sync can be obtained in a manner that the sum of or the difference between an input signal and a delay signal is calculated, without obtaining a simple correlation value between the input signal and the delay signal, and then a correlation value between a calculated signal and the delay signal is obtained.

In accordance with one aspect of the present invention, there is provided an apparatus for estimating a frequency offset. The apparatus includes a delay unit for delaying an input signal, a calculation unit for calculating a sum of or a difference between the input signal and a delay signal, a correlator for correlating a conjugate of a calculated signal with a conjugate of the delay signal and providing correlation values, a moving sum unit for summing output values of the correlator, a detector for detecting a specified point at which the correlation value becomes maximum, and a frequency offset calculator for estimating the frequency offset by calculating a phase change of a present signal against the delay signal at the specified point.

In accordance with another aspect of the present invention, there is provided a method for estimating a frequency offset. The method includes the steps of delaying an input signal, calculating a sum of or a difference between the input signal and a delay signal, correlating a conjugate of a calculated signal with a conjugate of the delay signal and providing correlation values, performing a moving sum of the correlation values, detecting a specified point at which the correlation value becomes maximum, and estimating the frequency offset by calculating a phase change of a present signal against the delay signal at the specified point.

### BRIEF DESCRIPTION OF THE DRAWINGS

The above and other objects, features, and advantages of the present invention will be more apparent from the following detailed description taken in conjunction with the accompanying drawings, in which:

FIG. 1 illustrates a preamble pattern used for an initial sync in a communication system;

FIGS. 2A and 2B are views illustrating a principle of obtaining a frequency offset;

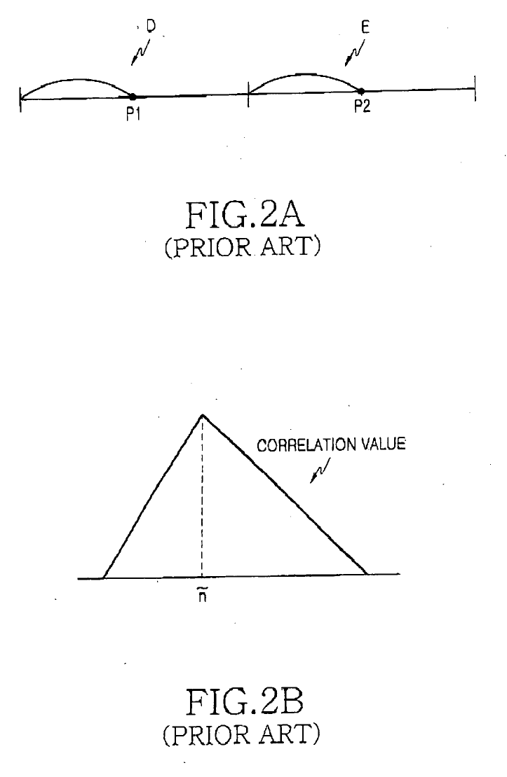

FIG. 3 is a block diagram of a conventional frequency offset estimating apparatus;

FIG. 4 is a block diagram of a frequency offset estimating apparatus according to an embodiment of the present invention;

FIG. 5 is a detailed circuit diagram of a frequency offset estimating apparatus according to an embodiment of the present invention; and

FIG. 6 is a flowchart illustrating a frequency offset estimating method according to an embodiment of the present invention.

### DETAILED DESCRIPTION OF THE PREFERRED EMBODIMENTS

Preferred embodiments of the present invention will be described in detail hereinafter with reference to the accompanying drawings. In the following description of the present invention, the same drawing reference numerals are used for the same elements even in different drawings. Although a number of specific features, such as an element, the number of pixels, a specified numeric key, etc., are given below, they are presented for a better understanding of the present invention only. Also, it will be clear to those skilled in the art that the present invention can easily be practiced without such specific features or through their modifications.

Additionally, a detailed description of known functions and configurations incorporated herein will be omitted when it may obscure the subject matter of the present invention.

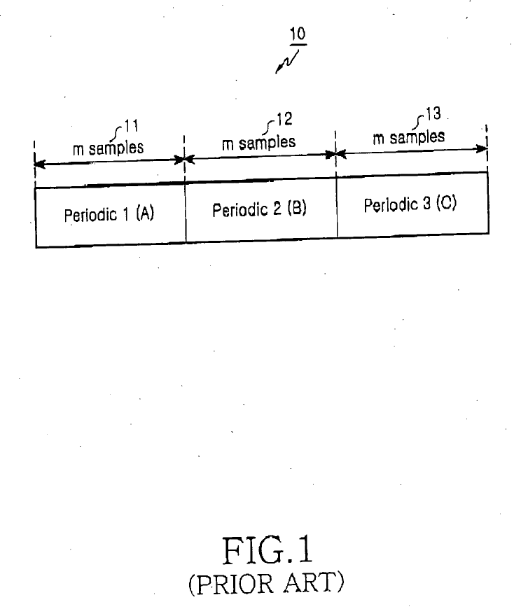

The present invention detects an initial sync, i.e., a start position of a frame, in a system that uses a periodically repeated preamble pattern to obtain a frame sync. Accordingly, a transmitter constructs and transmits a preamble as illustrated in FIG. 1. A receiver obtains the frame sync by searching for a position (i.e., section) having the largest correlation value by taking a correlation of the preamble pattern. In this case, a digital sample (time domain) received in the receiver includes the preamble pattern of FIG. 1, and this preamble pattern has repeated patterns.

In the embodiment of the present invention, the complexity of the receiver can be reduced by reducing the sections in which the moving sums are obtained using the characteristic of the repeated patterns. Accordingly, in the embodiment of the present invention, the sums of the repeated sections are obtained, and the correlation value thereof is obtained. More specifically, the receiver obtains the correlation of the preamble as expressed by Equation (1) in order to detect the start of the frame.

$$C [ n ] = {\sum }_{k = 0}^{2 m - 1} ( r ⋆ [ n + k ] r [ n + k - m ] ) \qquad ( 1 )$$

In Equation (1), r[k] denotes a k-th received signal sample, and r*[k] denotes a complex-conjugated value of r[k]. In this case, if n=0 and no noise exists, the correlation value can be divided into two sections, that is, a section from k=o to k=m−1 and a section from k=m to k=2m−1, as expressed by Equation (2).

$$\begin{matrix}{C}_{con} = {\sum }_{k = 0}^{m - 1} ( r ⋆ [ k ] r [ k - m ] ) + {\sum }_{k = m}^{2 m - 1} ( r ⋆ [ k ] r [ k - m ] ) \\ = {\sum }_{k = 0}^{m - 1} ( r ⋆ [ k ] r [ k - m ] ) + {\sum }_{k = 0}^{m - 1} ( r ⋆ [ m + k ] r [ k ] ) \\ = Correlation ( B , A ) + Correlation ( C , B ) \\ = 2 M\end{matrix} \qquad ( 2 )$$

Here, if the section from k=m to k=2m−b 1 is changed to the section from k=0 to k=m−1 with respect to the correlation value

$${\sum }_{k = m}^{2 m - 1} ( r ⋆ [ k ] r [ k - m ] )$$

of the section, the correlation value is changed to

$${\sum }_{k = 0}^{m - 1} ( r ⋆ [ m + k ] r [ k ] ) .$$

Accordingly, referring to FIG. 1, the correlation value between the conjugated period 2(B) and the period 1(A) becomes

$${\sum }_{k = 0}^{m - 1} ( r ⋆ [ k ] r [ k - m ] ) ,$$

and the correlation value between the conjugated period 3(C) and the period 2(B) becomes

$${\sum }_{k = 0}^{m - 1} ( r ⋆ [ m + k ] r [ k ] ) .$$

The correlation value that the receiver intends to obtain becomes Correlation(B,A)+Correlation(C,B). Here, because the r[k] has a period of m samples and the preamble pattern has the repeated patterns, the correlation value can be arranged as shown in Equation (3).

$$\begin{matrix}Correlation ( A , A ) = {\sum }_{k = 0}^{m - 1} ( r ⋆ [ k ] r [ k ] ) = M , \\ Correlation ( A , B ) = Correlation ( B , C ) \\ = {\sum }_{k = 0}^{m - 1} ( r ⋆ [ k ] r [ k - m ] ) = {\sum }_{k = 0}^{m - 1} ( r ⋆ [ k + m ] r [ k ] ) \\ = {\sum }_{k = 0}^{m - 1} ( r ⋆ [ k ] r [ k ] ) = M\end{matrix} \qquad ( 3 )$$

Here, if the frequency offset exists, the signal delayed for m samples is compared with the present sample to cause a specified phase change, which is expressed by Equation (4).
r[k−m]=r[k]e^{jΘ}
r[k+m]=r[k]e^{-jΘ} (4)

Meanwhile, the correlation value obtained using Equations (2) and (3) is expressed by Equation (5).

$$\begin{matrix}{C}_{con} = {\sum }_{k = 0}^{2 m - 1} ( r ⋆ [ k ] r [ k - m ] ) = {\sum }_{k = 0}^{2 m - 1} ( r ⋆ [ k ] r [ k ] {ⅇ}^{j Θ} ) \\ = {ⅇ}^{j Θ } {\sum }_{k = 0}^{2 m - 1} ( r ⋆ [ k ] r [ k ] ) = 2 M {ⅇ}^{j Θ}\end{matrix} \qquad ( 5 )$$

The frequency shift Θ given as above has a relation as shown in Equation (6) with the frequency offset.

$$Θ = \frac{2 π {F}_{off}}{N} \times \frac{N}{3} \qquad ( 6 )$$

In Equation (6), N is an FFT point number, and N/3 is given to the equation because the construction of FIG. 1 has a period for ⅓ section of the FFF point. Using the correlation value C_{COR}, the phase shift Θ can be obtained as expressed by

$$\begin{matrix}Equation ( 7 ) & \\ Θ = {tan}^{- 1} \frac{Im \{ {C}_{cor} \}}{Re \{ {C}_{cor} \}} . & ( 7 )\end{matrix}$$

The Accordingly, the estimated frequency offset is expressed by Equation (8).

$${F}_{offset} = \frac{3}{2 π} \times {tan}^{- 1} \frac{Im \{ {C}_{cor} \}}{Re \{ {C}_{cor} \}} \qquad ( 8 )$$

The frequency offset value obtained as above is used to control an oscillator through a loop filter.

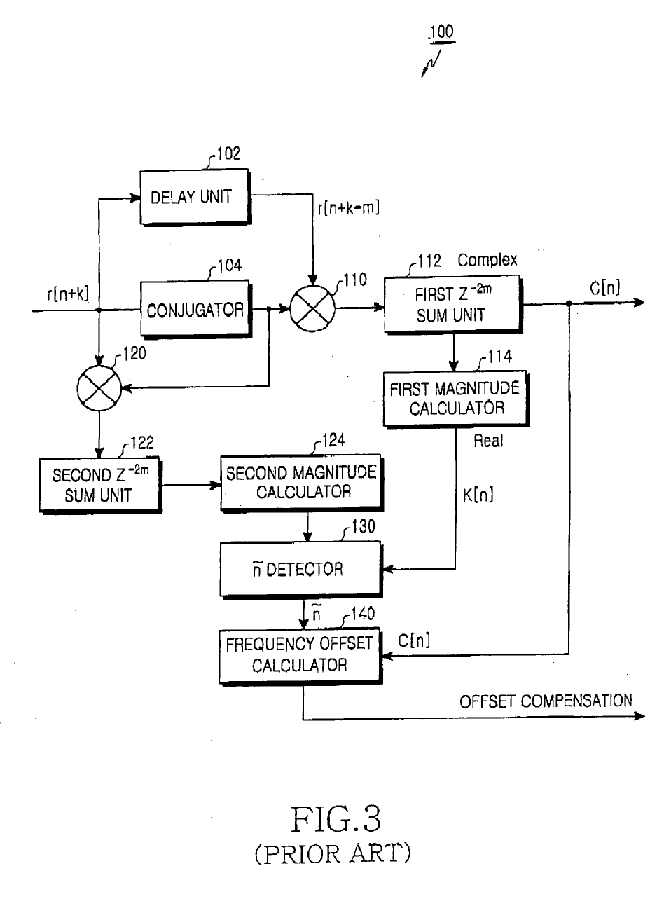

FIG. 3 is a block diagram of a conventional frequency offset estimating apparatus. Referring to FIG. 3, the conventional frequency offset estimating apparatus includes a delay unit 102, a conjugator 104, a first correlator 110, a first Z^{-2m} moving sum unit 112, a first magnitude calculator 114, a second correlator 120, a second Z^{-2m} moving sum unit 122, a second magnitude calculator 124, an ñ detector 130, and a frequency offset calculator 140.

If a signal is input to the frequency offset estimating apparatus 100, the input signal is provided to the delay unit 102 and the conjugator 104. The delay unit 102 delays the input signal for a period corresponding to m samples. Accordingly, the delay unit 102 delays the input signal r[n+k] by m samples, and outputs a signal r[n+k−m] to the second correlator 110. The conjugator 104 conjugates the input signal r[n+k] and outputs the conjugated signal to the first correlator 110. The first correlator 110 has an input part connected to an output part of the delay unit 102 and an output part of the conjugator 104.

The first correlator 110 correlates the output signal of the delay unit 102 and the output signal of the conjugator 104, and outputs a correlation value to the first Z^{-2m} moving sum unit 112. The first Z^{-2m} moving sum unit 112 sums the correlation values output from the first correlator 110, and in particular, performs an accumulative summing of 2m samples.

As described above, because the repeated patterns have three periods, the correlation value between the repeated pattern of the first period and the repeated pattern of the second period and the correlation value between the repeated pattern of the second period and the repeated pattern of the third period should accumulatively be summed. More specifically, if the respective signal period includes m samples, the first Z^{-2m} moving sum unit 112 accumulatively sums 2m samples and the summed value to the frequency offset calculator 140 and the first magnitude calculator 114. The output of the first Z^{-2m} moving sum unit 112 has a complex value including an imaginary value and a real value, and the frequency offset calculator 140 can calculate the frequency offset from the output signal of the first Z^{-2m} moving sum unit 112.

Additionally, in order to acquire the sync of the frame, the output signal of the first Z^{-2m} moving sum unit 112 is provided to the first magnitude calculator 114. The first magnitude calculator 114 calculates the magnitude of the output signal of the first Z^{-2m} moving sum unit 112 and outputs the calculated signal to the ñ detector 130.

The second correlator 120 receives the signal input from the frequency offset estimating apparatus 100 and the output signal of the conjugator 104. In this case, the second correlator 120 correlates the input signal with the output signal of the conjugator 104, and outputs the correlation value to the second Z^{-2m} moving sum unit 122. The second Z^{-2m} moving sum unit 122 accumulatively sums the correlation value output from the second correlator 120 for a period of 2m samples and outputs the summed value to the second magnitude calculator 124. The second magnitude calculator 124 has an input part connected to the output part of the second Z^{-2m} moving sum unit 122, and if the output signal of the second Z^{-2m} moving sum unit 122 is provided, it calculates the magnitude of the output signal to output the calculated signal to the ñ detector 130.

The ñ detector 130 detects the point ñ at which the magnitude of the correlation value of the repeated patterns maximizes on the basis of the magnitude of the correlation value of the specified section of the presently input signal and the magnitude of the correlation value of the specified section of the delay signal. The ñ detector 130 outputs the detected point ñ to the frequency offset calculator 140. The frequency offset calculator 140 calculates the frequency offset from the correlation value of the ñ point among the correlation values output from the first Z^{-2m} moving sum unit 112.

In the conventional frequency offset estimating apparatus as described above, the first Z^{-2m} moving sum unit 112, for example, accumulatively sums the correlation value between the repeated pattern of the first period A 11 and the repeated pattern of the second period B 12 and the correlation value between the repeated pattern of the second period B 12 and the repeated pattern of the third period C 13. Therefore, if the respective signal period includes m samples, it accumulatively sums the correlation values from the first correlator 110 for a period of 2m samples.

The present invention reduces the complexity of the conventional frequency offset estimating apparatus that should accumulatively sum the correlation values for a period of 2m samples. More specifically, in the embodiment of the present invention, the complexity of the receiver is reduced by reducing the section in which the moving sum is obtained using the characteristic of the repeated patterns. For this, in the embodiment of the present invention, the sum of or the difference between the input signal and the delay signal of the repeated section is obtained and then the correlation value thereof is obtained. Because the preamble signal has the same repeated sections 11, 12, and 13, the sum of or the difference between the input signal and the delay signal is calculated instead of obtaining the simple correlation value between the input signal and the delay signal. Thereafter, the correlation value between the calculated signal and the delay signal is obtained.

More specifically, in the present invention, the sum of or the difference between the input signal of the frequency offset estimating apparatus and the delay signal thereof is calculated when ‘K[n]’ input to the ñ detector and ‘C[n]’ input to the frequency offset calculator are obtained.

In order to explain the construction of the present invention, ‘K[n]’ and ‘C[n]’ are expressed in Equation (9) below.

$$\begin{matrix}K [ n ] = {\sum }_{k = 0}^{m - 1} ( ( r [ n + k ] + r [ n + k - 2 m ] ) r * [ n + k - m ] ) , \\ C [ n ] = {\sum }_{k = 0}^{m - 1} ( ( r [ n + k ] - r [ n + k - 2 m ] ) r * [ n + k - m ] )\end{matrix} \qquad ( 9 )$$

Additionally, by arranging Equation (9) using the relation of Equation (4), Equation (10) can be obtained. As shown in Equation (10), the newly obtained value K is a real number and the value C is given as an imaginary number.

$$\begin{matrix}K = {\sum }_{k = 0}^{m - 1} ( ( r [ m + k ] + r [ k - m ] ) r * [ k ] ) \\ = {\sum }_{k = 0}^{m - 1} ( r [ m + k ] r * [ k ] ) + {\sum }_{k = 0}^{m - 1} ( r [ k - m ] ) r * [ k ] ) \\ = Correlation ( C , B ) {ⅇ}^{- j Θ} + Correlation ( A , B ) {ⅇ}^{j Θ} \\ = M ( {ⅇ}^{- j Θ} + {ⅇ}^{j Θ} ) \\ = 2 M cos Θ , \\ C = {\sum }_{k = 0}^{m - 1} ( ( r [ m + k ] - r [ k - m ] ) r * [ k ] ) \\ = {\sum }_{k = 0}^{m - 1} ( r [ m + k ] r * [ k ] ) - {\sum }_{k = 0}^{m - 1} ( r [ k - m ] ) r * [ k ] ) \\ = Correlation ( C , B ) {ⅇ}^{- j Θ} - Correlation ( A , B ) {ⅇ}^{j Θ} \\ = M ( {ⅇ}^{- j Θ} - {ⅇ}^{j Θ} ) \\ = - 2 M j sin Θ\end{matrix} \qquad ( 10 )$$

In Equation (10), the value C[n] may be calculated in a modified form such as r[k−m]−r[m+k] within the scope of the present invention. According to Equation (9), the frequency offset can be given as shown in Equation (11).

$${F}_{offset} = \frac{3}{2 π} \times {sin}^{- 1} \frac{C [ n ]}{S [ n ]} \qquad ( 11 )$$

More specifically, C[n] does not have a complex value but has an imaginary value, and K[n] does not have a complex value but has a real value. This means that the ñ detector requires only the magnitude value of the signal and the frequency offset calculator requires only the phase value in the frequency offset estimating apparatus. Accordingly, in the present invention, the frequency offset calculator calculates the phase change of the signal, and it does not use the real value, i.e., the magnitude value.

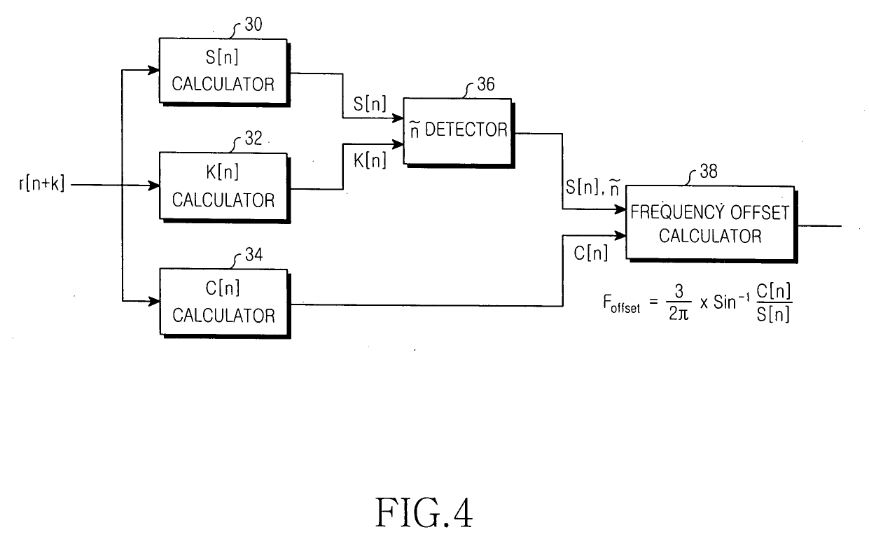

FIG. 4 is a block diagram of the frequency offset estimating apparatus according to an embodiment of the present invention. Referring to FIG. 4, the frequency offset estimating apparatus includes an S[n] calculating unit 30, a K[n] calculating unit 32, a C[n] calculating unit 34, an ñ detector 36, and a frequency offset calculator 38. The S[n] calculating unit 30 correlates the input signal and its conjugated signal for a specified section and outputs S[n].

The K[n] calculating unit 32 delays the input signal, calculates the sum of a delay signal and the input signal for a specified section, and then correlates the calculated signal with the delay signal to output K[n]. The C[n] calculating unit 34 delays the input signal, calculates the sum of a delay signal and the input signal for a specified section, and correlates the calculated signal with the delay signal to output C[n]. As described above, C[n] includes the imaginary value only.

The output part of the S[n] calculating unit 30 and the output part of the K[n] calculating unit are connected to the input part of the ñ detector 36. The ñ detector 36 detects the point ñ at which the magnitude of the correlation value of the repeated patterns becomes maximum. The ñ detector 36 divides the magnitude of the correlation value of the specified section of the delay signal by the magnitude of the correlation value of the specified section of the present input signal, and determines the point at which the quotient becomes maximum as the point ñ. More specifically, the ñ detector 36 searches for the ñ value that maximizes D(n)=K(n)/S(n), and outputs the ñ value and S[n] to the frequency offset calculator 38. The frequency offset calculator 38 calculates the phase change of the signal, and thus does not use the real value of the signal, i.e., the magnitude value. The frequency offset calculator 38 calculates the phase change of S[n] that is the present signal corresponding to the delay signal C[n] at the point ñ according to the output from the ñ detector 36 using Equation (11).

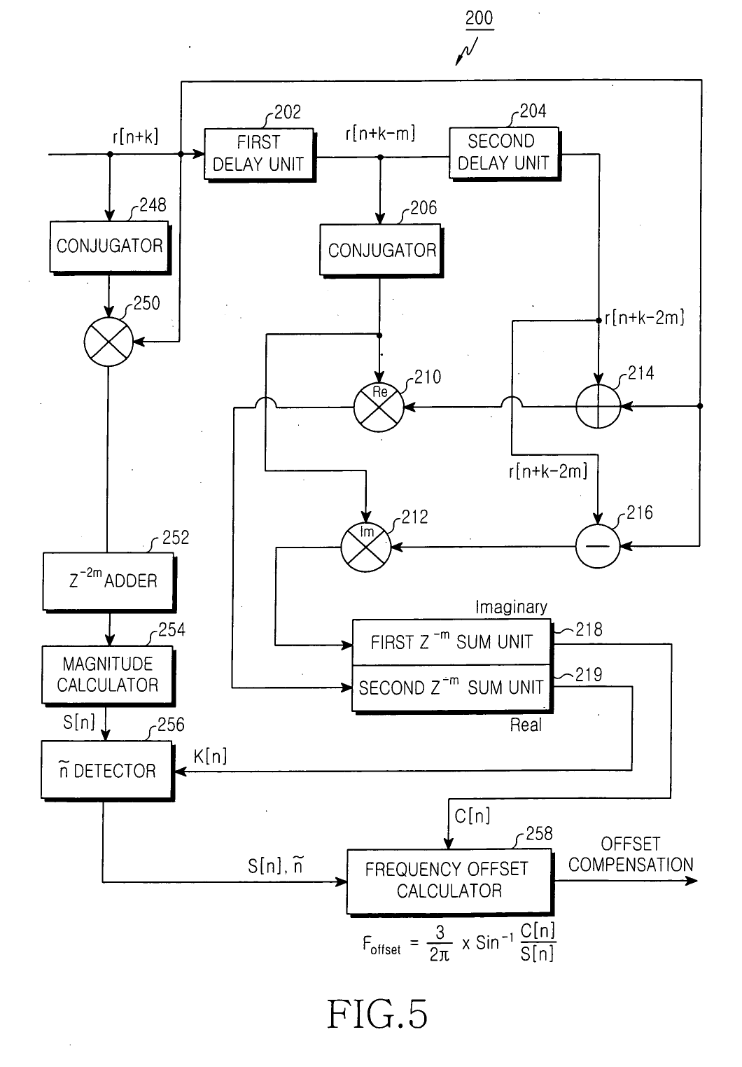

FIG. 5 is a detailed circuit diagram of the frequency offset estimating apparatus according to an embodiment of the present invention. The frequency offset estimating apparatus 200 of FIG. 5 is constructed to provide only the necessary signal components to an ñ detector 256 and a frequency offset calculator 258.

Referring to FIG. 5, the frequency offset estimating apparatus 200 includes a conjugator 248, a correlator 250, a Z^{-2m} moving sum unit 252, and a magnitude calculator 254. The frequency offset estimating apparatus 200 further includes a first delay unit 202, a conjugator 206, a second delay unit 204, an adder 214, a subtracter 216, a real-number correlator 210, an imaginary-number correlator 212, a first Z^{-m} moving sum unit 218, and a second Z^{-m} moving sum unit 219.

The first delay unit 202 delays the input signal for a period corresponding to m samples. Accordingly, the first delay unit 202 delays the input signal r[n+k] by m samples, and outputs a signal r[n+k−m]. The conjugator 206 conjugates the signal r[n+k−m] and outputs the conjugated signal to the real-number correlator 210 and the imaginary-number correlator 212. The second delay unit 204 delays the signal r[n+k−m] output from the first delay unit 202 for a period corresponding to m samples, and outputs a signal r[n+k−2m] to the adder 214 and the subtracter 216. The input signal r[n+k] and the signal r[n+k−2m] output from the second delay unit 204 are input to the adder 214 and the subtracter 216.

The adder 214 adds the input signal and the signal from the second delay unit 204, and outputs a signal of a real-number value to the real-number correlator 210. The subtracter 216 subtracts the signal from the second delay unit 204 from the input signal, and outputs a signal of an imaginary-number value to the correlator 212.

The real-number correlator 210 correlates the signal of the real number provided from the adder 214 with the conjugated value r*[n+k−m] of r[n+k−m] output from the conjugator 206, and outputs the correlation value of the real number to the second Z^{-m} moving sum unit 219. The second Z^{-m} moving sum unit 219 receives the correlation value of the real number from the real-number correlator 212 and performs the summing of m samples.

The frequency offset estimating apparatus according to the present invention further includes the ñ detector 256 and the frequency offset calculator 258. The ñ detector 256 receives S[n] from the magnitude calculator 254 and K[n] from the second Z^{-m} moving sum unit 219. The ñ detector 256 detects the point ñ at which the magnitude of the correlation value of the repeated patterns becomes maximum, and thus it does not use the imaginary-number value of the signal, i.e., the phase value. More specifically, the ñ detector 256 determines the point at which the quotient obtained by dividing the magnitude K[n] of the correlation value of the specified section of the delay signal by the magnitude S[n] of the correlation value of the specified section of the present input signal becomes maximum as the point ñ. That is, the ñ detector 256 searches for the ñ value that maximizes D(n)=K(n)/S(n), and outputs the results to the frequency offset calculator 258.

The imaginary-number correlator 212 correlates the signal of the imaginary number provided from the subtracter 216 with the conjugated value r*[n+k−m] of r[n+k−m] output from the conjugator 206, and outputs the correlation value of the imaginary number to the first Z^{-m} moving sum unit 218. The first Z^{-m} moving sum unit 218 receives the correlation value of the imaginary number from the imaginary-number correlator 212 and sums m samples to provide the resultant value to the frequency offset calculator 258. The frequency offset calculator 258 calculates the phase change of the signal, and thus does not use the real value of the signal, i.e., the magnitude value.

The frequency offset calculator 258 calculates the phase change of S[n] that is the present signal with respect to the delay signal C[n] at the point ñ according to the output from the ñ detector 256 using Equation (1).

In FIG. 5, two Z^{-m} moving sum units 218 and 219 are provided in the frequency offset estimating apparatus, but they correspond to one complex-number Z^{-m} moving sum unit in practice. Accordingly, the actual complexity is greatly reduced in comparison to the Z^{-m} moving sum unit of the conventional frequency offset estimating apparatus. Additionally, the two complex-number multipliers, i.e., the two correlators 210 and 212, in FIG. 5 are constructed to calculate only the real value and the imaginary value, and thus they have the same complexity as one complex-number multiplier.

The reference signs ‘Re’ and ‘Im’ in the respective correlators 201 and 212 in FIG. 5 are to indicate that they are circuits for calculating only the real value or the imaginary value of the resultant value when they multiply the two complex values.

The features of the frequency offset estimating apparatus according to the present invention in comparison to those of the conventional frequency offset estimating apparatus are shown in Table 1 below.

TABLE 1

| | | Present | |
|---|---|---|---|
| Classification | Prior Art | Invention | Remarks |
| Conjugate | Two | Two | * Both are of a complex |
| | | | type, and I and Q mean |
| | | | the respective numbers |
| | | | of bits. |
| Delay | m | 2 m | * m = [2048/3] = 683 |
| Element | | | (802.16 OFDMA) |
| (12 bits) | | | |
| Add/Subtract | | Two | * Adders/subtracters |
| | | | used in the moving sum |
| | | | adders are excluded. |
| Multiply | 12 × 12 bits | One Real | Same as one complex- |
| | | Value One | number multiply |
| | | Imaginary | |
| | | Value | |
| Moving | 2 m (24 bits) | m (25 bits) | The present invention |
| Sum | | | can reduce the number of |
| | | | delay elements having |
| | | | a large number of bits. |

As shown in Table 1, the frequency offset estimating apparatus according to the present invention can reduce the complexity of the receiver by reducing the section in which the moving sum unit obtains the moving sums in comparison to the conventional frequency offset estimating apparatus.

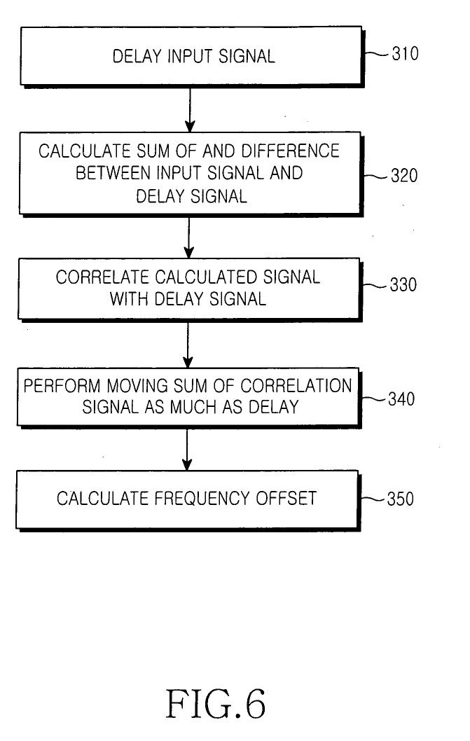

FIG. 6 is a flowchart illustrating a frequency offset estimating method according to an embodiment of the present invention. Referring to FIG. 6, if a signal having a periodically repeated structure is received, the delay units 202 and 204 of the frequency offset estimating apparatus according the present invention delay the signal for a period corresponding to m samples in step 310. In this case, m may be the number of samples included in the repeated period. The adder 212 and the subtracter 214 of the frequency offset estimating apparatus calculate the sum of and the difference between the delay signal and the presently input signal in step 320. The correlators 210 and 212 correlate the conjugates of the calculated signal and the delay signal, and the first and second moving sum units 218 and 219 sum the correlation signals from the correlators 210 and 212 for m repeated periods in step 340. The first Z^{-m} moving sum unit 218 receives the correlation value of the imaginary number from the correlator 212 and performs a moving sum of m samples. The second Z^{-m} moving sum unit 219 receives the correlation value of the real number from the correlator 210 and performs a moving sum of m samples.

The frequency offset calculator 258 of the frequency offset estimating apparatus calculates the phase change of the present signal with respect to the delay signal at the point ñ according to the output from the ñ detector 256 using Equation (11) in step 350.

In order to obtain an accurate estimation of the frequency offset, the timing sync should accurately be matched. The timing sync is for the ñ detector to accurately search for the point at which the correlation value maximizes, which is not included in the present invention. In order to estimate the timing sync more accurately, it may be required to repeatedly perform the estimation or to permit a slight offset at the position in which the maximum value is estimated in some cases.

In the embodiment of the present invention as described above, the value ñ, when the value K is greatest, is searched for and the frequency offset is estimated using the value C[n] at that time. Because the parts for obtaining the magnitude value S[n] have the same complexity, they are excluded from the comparison in Table 1. As shown in Table 1, the number of 25-bit delay elements can be reduced as many as m(=682 in the case of 802.16) through the present invention.

Additionally, in the embodiments as described above, the circuit of obtaining S[n] is only exemplary and can be replaced by other circuits for obtaining the magnitude value of the signal.

Additionally, to take the imaginary value and the real value in the embodiment of the present invention is to minimize the complexity of the circuit. It is also possible to extract the magnitude information about the entire complex value.

As described above, according to the present invention, the sums of the repeated sections are obtained and then the correlation values thereof are obtained. Accordingly, the section in which the moving sum is obtained is reduced, and thus the complexity of the receiver can be reduced.

In the embodiments of the present invention, the frequency offset estimating apparatus is applied to the OFDMA type frame sync extraction of the 802.16 standard. However, the present invention can also be applied to other systems for achieving the frame sync by delay and correlation using repeated preamble patterns.

From the foregoing, it will be apparent that the present invention has the advantages that its circuit construction is simplified with low power consumption by reducing the implementation complexity of the frequency offset estimating apparatus. Accordingly, the battery cycle of a terminal provided with the frequency offset estimating circuit can be increased.

While the present invention has been shown and described with reference to certain preferred embodiments thereof, it will be understood by those skilled in the art that various changes in form and details may be made therein without departing from the spirit and scope of the present invention as defined by the appended claims.

What is claimed is:

1. An apparatus for estimating a frequency offset in a signal having a periodically repeated structure, the apparatus comprising:
a delay unit for delaying an input signal;
a calculation unit for calculating one of a sum of and a difference between the input signal and a delay signal;
a correlator for correlating a conjugate of a calculated signal with a conjugate of the delay signal and providing correlation values;
a moving sum unit for summing output values of the correlator;
a detector for detecting a specified point at which the correlation value becomes maximum; and
a frequency offset calculator for estimating the frequency offset by calculating a phase change of a present signal against the delay signal at the specified point.

2. The apparatus as claimed in claim 1, wherein the delay unit comprises:
a first delay unit for delaying the input signal for a period of repeated patterns and providing a first delay signal; and
a second delay unit for delaying the first delay signal from the first delay unit for the period of the repeated patterns and providing a second delay signal.

3. The apparatus as claimed in claim 2, wherein the calculation unit comprises:
an adder for calculating a sum of the input signal and the second delay signal from the second delay unit; and
a subtracter for calculating a difference between the input signal and the second delay signal from the second delay.

4. The apparatus as claimed in claim 3, wherein the correlator comprises:
a first correlator for correlating an output of the adder with a conjugate of the delay signal; and
a second correlator for correlating an output of the subtracter with the conjugate of the delay signal.

5. The apparatus as claimed in claim 4, wherein the moving sum unit comprises:
a first moving sum unit for accumulating an output of the first correlator for the period of the repeated patterns to output an accumulated signal; and
a second moving sum unit for accumulating an output of the second correlator for the period of the repeated patterns to output an accumulated signal.

6. The apparatus as claimed in claim 1, wherein the frequency offset calculator calculates the frequency offset using:
$${F}_{offser} = \frac{3}{2 π} \times {sin}^{- 1} \frac{C [ n ]}{S [ n ]} ,$$
where C[n] denotes the delay signal having an imaginary value and S[n] denotes the present signal.

7. A method for estimating a frequency offset in a signal having a periodically repeated structure, the method comprising the steps of:
delaying an input signal;
calculating one of a sum of and a difference between the input signal and a delay signal;
correlating a conjugate of a calculated signal with a conjugate of the delay signal;
providing correlation values;
performing a moving sum of the correlation values;
detecting a specified point at which the correlation value becomes maximum; and
estimating the frequency offset by calculating a phase change of a present signal against the delay signal at the specified point.

8. The method as claimed in claim 7, wherein the step of delaying the input signal comprises the steps of:
a first delaying step of delaying the input signal for a period of a repeated patterns;
providing a first delay signal;
a second delaying step of delaying the first delay signal for the period of the repeated patterns; and
providing a second delay signal.

9. The method as claimed in claim 8, wherein the step of calculating the one of the sum of and the difference between the input signal and the delay signal comprises the steps of:
calculating a sum of the input signal and the second delay signal; and
calculating a difference between the input signal and the second delay signal.

10. The method as claimed in claim 9, wherein the step of correlating the conjugate of the calculated signal with the conjugate of the delay signal comprises the steps of:
correlating an added signal with a conjugate of the delay signal; and
correlating an subtracted signal with the conjugate of the delay signal.

11. The method as claimed in claim 10, wherein the step of performing a moving sum of the correlation values comprises the steps of:
performing the moving sum of the first correlation signal for the period of the repeated patterns to output an accumulated signal; and
performing the moving sum of the second correlation signal for the period of the repeated patterns to output an accumulated signal.

12. The method as claimed in claim 7, wherein the frequency offset is calculated using:
$${F}_{offser} = \frac{3}{2 π} \times {sin}^{- 1} \frac{C [ n ]}{S [ n ]} ,$$
where C[n] denotes the delay signal having an imaginary value and S[n] denotes the present signal.
